(19) United States
(12) Patent Application Publication
(10) Pub. No.: US 2024/0142537 A1
(43) Pub. Date: May 2, 2024

(54) Method for ascertaining a proportion of defective battery cells, battery controller, computer program, computer-readable storage medium, battery and motor vehicle

(71) Applicant: Webasto SE, Stockdorf (DE)

(72) Inventors: David Bennets, Stockdorf (DE); Samantha Zimnik, Stockdorf (DE)

(21) Appl. No.: 18/384,447

(22) Filed: Oct. 27, 2023

(30) Foreign Application Priority Data
Oct. 28, 2022 (DE) 102022128702.5

(51) Int. Cl. G01R 31/396; G01R 31/367; G01R 31/3835

(52) U.S. Cl. CPC G01R 31/396; G01R 31/367; G01R 31/3835

(57) ABSTRACT

The present invention relates to a method for determining a proportion of defective battery cells in a group of battery cells connected electrically in parallel in a battery, where a voltage state of a terminal voltage of the group is determined in relation to a charging process and/or in relation to a relaxation of the battery under an environmental condition and a deviation of the determined voltage state of the terminal voltage from the voltage state of the terminal voltage of the same group from a previous charging process and/or a previous relaxation under the same environmental condition is calculated, where the proportion of defective battery cells in the group is determined from the calculated deviation.

### CROSS-REFERENCE TO RELATED APPLICATION

This application claims priority to German Application No. DE 10 2022 128 702.5 filed on Oct. 28, 2022, which is incorporated herein by reference in its entirety for all purposes.

### TECHNICAL FIELD

The present invention relates to a method for ascertaining a proportion of defective battery cells in a battery, to a battery controller, to a computer program, to a computer-readable storage medium, to a battery and to a motor vehicle.

### BACKGROUND

A battery may comprise healthy and defective battery cells. The battery cells of the battery may age at different rates over time and/or due to environmental influences and/or due to manufacturing defects and/or manufacturing tolerances. This may cause healthy battery cells to age prematurely and become defective. Defective battery cells have an increased internal electrical resistance and have charging behaviour different from healthy battery cells in the battery.

A defective battery cell may lead to increased heat development during a charging process or during a discharging process of the battery, and may additionally cause undesirable compensation currents from the healthy battery cells to the defective battery cells within the battery. The defective battery cells may therefore damage the healthy battery cells in the battery, and in particular in a group of battery cells connected to one another in parallel.

Therefore, battery cells may have a circuit breaker that electrically disconnects them from the other battery cells in a group of battery cells, but the circuit breaker does not provide any feedback to the battery management system. It is therefore necessary to estimate the proportion of defective and in particular disconnected battery cells in the battery, and to electrically isolate those parts of the battery that have an excessive number of defective battery cells from the battery.

EP 3 951 411 A1 discloses a method and a system for detecting connection errors in a parallel connection cell. EP 2 343 768 A2 discloses a battery system and a method for identifying the current-limiting state in a battery system. US 2019/0198945 A1 discloses a secondary battery system and methods for diagnosing anomalies in a set of batteries. US 2021/0165054 A1 discloses a method for detecting contact errors in a rechargeable set of batteries and a system for performing the method. EP 2 306 214 A3 discloses a method for determining a DC resistance of a battery. EP 3 252 914 B1 discloses a device and a method for detecting the opening of the current interruption to device of a battery unit.

### DISCLOSURE OF THE INVENTION

Proceeding from the known prior art, one object of the present invention is to provide an improved method for determining a proportion of defective battery cells, along with a corresponding battery controller, a computer program, a computer-readable storage medium, a battery and a motor vehicle.

The object is achieved by a method having the features of claims 1 and/or 2. Advantageous developments of the method will become apparent from the dependent claims, along with the present description and the figures.

What is accordingly proposed is a method for determining a proportion of defective battery cells in a group of battery cells connected electrically in parallel in a battery, wherein a voltage state of a terminal voltage of the group is determined in relation to a charging process and/or in relation to a relaxation of the battery under an environmental condition and a deviation and additionally a rate of change of the deviation of the determined voltage state of the terminal voltage from the voltage state of the terminal voltage of the same group from a previous charging process and/or a previous relaxation under the same environmental condition is calculated, wherein the proportion of defective battery cells in the group is determined from the calculated deviation and additionally from the rate of change of the deviation.

In addition or as an alternative, what is proposed is a method for determining a proportion of defective battery cells in a group of battery cells connected electrically in parallel in a battery, wherein the voltage state of the terminal voltage of the group is determined in relation to the charging process and/or in relation to the relaxation of the battery under an environmental condition and a deviation and additionally a rate of change of the deviation of the determined voltage state of the terminal voltage from a voltage state of the terminal voltage of at least one other group of the battery and/or from an average value of the voltage state of the respective terminal voltage of at least two groups of the battery is calculated, wherein the proportion of defective battery cells in the group is determined from the calculated deviation and additionally from the rate of change of the deviation. By way of example, the proportion of defective battery cells in the group may be determined by way of a comparison of the deviation with a stored deviation threshold value.

In addition, a rate of change of the deviation may be determined by way of a comparison of the calculated deviation in relation to a current charging process with the calculated deviation from at least one previous charging process, in particular in relation to a reference value from a previous charging process. By way of example, the calculated deviation from the previous charging process may be used in each case as a reference value for determining the rate of change. If for example the rate of change exceeds a threshold value in relation to the reference value, in particular if a jump in the rate of change is detected, it may be determined that a swap from an old group to a new group has taken place. In this case, the calculated deviation may be stored as a new reference value, wherein the respective group remains connected if the rate of change exceeds said threshold value. If the rate of change falls below the threshold value, in particular no jump in the rate of change is detected, it may be determined that the calculated deviation in relation to the charging process is caused by ageing of the battery cells in the group and/or by manufacturing tolerances.

This results in the advantage that a false alarm and incorrect disconnection of the group may be avoided when an old group is swapped for a new group in the battery system. Said methods may therefore also be used in battery systems that consist of new and used groups of battery cells, that is to say what is known as a second-life battery system.

The environmental condition may be an environmental condition limited to a reproducible situation. In other words, the environmental condition may be chosen such that it is able to be reproduced in another charging process.

An environmental condition limited to a reproducible situation may be limiting of the determination of the voltage state of the terminal voltage to one parameter. The parameter may be for example a charging current or discharging current and/or a temperature and/or a state of charge of the battery. The voltage state of the terminal voltage may be determined in relation to said parameter.

The battery may be designed for use in a motor vehicle, and in particular be provided as a distributed battery system. The battery or the battery system may thus comprise at least one group of battery cells that are each connected electrically in parallel. The groups in the battery may be connected electrically in series with one another. The respective group in the battery may have a measuring apparatus for measuring a voltage, for example the terminal voltage, and/or a charging current or a discharging current, which measuring apparatus is connected to a battery controller via a data line.

A charging start time of the charging process may be detected by way of measuring the charging current or discharging current and/or by way of receiving a user input, wherein the charging start time may be determined as the time at which the measured charging current or discharging current is other than zero.

The battery controller may for example determine the voltage state of the terminal voltage of the respective group only when the environmental condition of the current charging process is the same environmental condition as or an environmental condition similar to the environmental condition of the previous charging process.

In relation to a charging process and/or to a relaxation may mean before and/or during and/or after the charging process and/or the relaxation. A relaxation may comprise a time of inactivity or a rest period of the battery.

The average value may be the average of the voltage state of the terminal voltage, in particular the voltage level and/or the voltage drop, of at least two groups or all groups of the battery.

In addition, the charging start time may be calculated by way of the charging current or discharging current of the charging device, for example by way of a battery controller, such that a charging target received by way of a user input is always achieved at the charging target time, such as for example 6:00 a.m. The charging target may in this case specify a charging reference state of the battery after the charging process. Starting the charging process after the rest period makes it possible to reduce distortion of the estimation due to hysteresis of the battery cells during the discharging and charging process.

During the charging process, for example during a start-up phase, in particular a constant current phase of the charging process, the terminal voltage of the respective group may be measured at time intervals by way of the measuring apparatus, and the measured value may optionally be stored in a memory together with the measurement time.

The voltage state of the terminal voltage during the charging process may be determined, for example by way of a processor unit, from the respective data pair of the measured value and the measurement time of the terminal voltage of the group. The time intervals may be periodic or oriented according to a specified number of data pairs during the start-up phase, in particular during the constant current phase of the charging process. The number of specified data pairs may be higher during the start-up phase, in particular during the constant current phase, than in other phases of the charging process. By way of example, the time interval, such as for example a sampling rate, may be shortened during the start-up phase of the charging process for better data collection.

In addition, the voltage state of the terminal voltage may be determined during a rise in the terminal voltage with a reference gradient.

The voltage state of the terminal voltage may be determined after the charging start time, for example in a first half or in a first quarter of the charging time after the charging start time.

The voltage state of the terminal voltage of the respective group may be determined under at least one environmental condition.

The environmental condition may be a parameter, such as for example a temperature and/or a state of charge of the battery and/or a rest period of the battery. The environmental condition of the charging process may be the same environmental condition as or an environmental condition similar to the previous charging process if the respective parameters of the environmental condition are each the same and/or are within a tolerance interval around a reference value of the respective parameter.

The rest period may for example amount at least partially to the relaxation time of the battery, such as for example at least three quarters of the relaxation time. By way of example, the voltage state of the terminal voltage is determined when the rest period amounts at least to the relaxation time.

A deviation of the voltage state of the terminal voltage of the group from the charging process may be calculated with the voltage state of the terminal voltage of the same group from a previous charging process under the same environmental condition and/or with the voltage state of the terminal voltage of another group of the battery from the same or a previous charging process under the same environmental condition. The other group may in this case be structurally identical to the group under consideration. A structurally identical group may in this case be a group that has experienced the same environmental conditions as the group since production, for example in relation to temperature, charging current, discharging rate (driving style), age and charging cycles. The structurally identical group may thus be a group in which the rate of change of the deviation falls below the threshold value. Another group in which the rate of change of the deviation has exceeded the threshold value at least once may be excluded from the calculation of the deviation. The abovementioned detection of jumpy behaviour may therefore be suitable for detecting to disconnected cells with little misinformation despite different “ageing”. By way of example, a battery controller may for this purpose have a processor unit that calculates the deviation.

By way of example, the deviation may be calculated by adding the absolute values of the differences to form the respective measurement points. The deviation may thus be formed as a sum of the absolute differences of the measured values of the voltage state of the terminal voltage, for example as a sum of the differences of the respective data pairs at the respective times. In addition, the voltage state of the terminal voltage of the group from the current charging process may be stored in the memory together with the environmental condition. In addition, the respective voltage state of the terminal voltage may be logarithmized, by way of a filter element, for better data processing by a processor unit, in particular a microcontroller, and the respective deviation may then be calculated.

In addition or as an alternative, the deviation may be calculated from a comparison of the terminal voltage of the group with a reference value, which may for example be an average value of the temporal profiles of the terminal voltage of the other groups from a previous charging process under the same environmental condition and/or an average value of the temporal profiles of the terminal voltage of the other groups from the current charging process.

If the calculated deviation of the voltage state of the terminal voltage exceeds a deviation threshold value, which may for example be a voltage threshold value and/or a resistance threshold value, it is possible to determine a proportion of defective battery cells associated with the respective deviation threshold value.

If the proportion of defective battery cells falls below a proportion threshold value, such as for example 50 percent defective battery cells in the group, the group may remain electrically connected to the battery via a switching arrangement.

If the proportion of defective battery cells exceeds the proportion threshold value, the group may be electrically isolated from the other groups of the battery by way of at least one switching element of the switching arrangement and/or a charging current or a discharging current may be limited and/or a warning message may be output. The current charging process of the group containing an excessive number of defective battery cells is therefore not continued. After the warning message has been output, the motor vehicle may be taken to a workshop and the affected group may be replaced. A period with low performance would thereby be shortened. The warning message may for this purpose comprise a request to a user to visit a workshop.

The method in particular makes provision that the voltage state of the terminal voltage of the group is determined in relation to a charging process under an environmental condition limited to a reproducible situation and the deviation of the determined voltage state of the terminal voltage from the voltage state of the terminal voltage of the same group from a previous charging process under the same environmental condition, on the one hand, and/or from the voltage state of the terminal voltage of at least one other group of the battery and/or from an average value of the voltage state of the respective terminal voltage of at least two groups of the battery, on the other hand, is calculated. The voltage state of the terminal voltage of the at least one other group and/or the average value of the voltage state of the respective terminal voltage of at least two groups of the battery may in this case be from the same charging process and/or from a previous charging process additionally under the same environmental condition.

The method may also make provision that the voltage state of the terminal voltage of the group is determined in relation to a relaxation under an environmental condition limited to a reproducible situation and the deviation of the determined voltage state of the terminal voltage from the voltage state of the terminal voltage of the same group from a previous relaxation under the same environmental condition, on the one hand, and/or from the voltage state of the terminal voltage of at least one other group of the battery and/or from an average value of the voltage state of the respective terminal voltage of at least two groups of the battery, on the other hand, is calculated. The voltage state of the terminal voltage of the at least one other group and/or the average value of the voltage state of the respective terminal voltage of at least two groups of the battery may in this case be from the same relaxation and/or from a previous relaxation additionally under the same environmental condition.

The method may furthermore make provision that the voltage state of the terminal voltage of the group is determined in relation to a charging process and a relaxation under an environmental condition limited to a reproducible situation and the deviation of the determined voltage state of the terminal voltage from the voltage state of the terminal voltage of the same group from a previous charging process and a previous relaxation under the same environmental condition is calculated. The previous relaxation may in this case be before and/or after the previous charging process.

The method may also make provision that the voltage state of the terminal voltage of the group is determined in relation to a charging process and a relaxation under an environmental condition limited to a reproducible situation and the deviation of the determined voltage state of the terminal voltage from the voltage state of the terminal voltage of at least one other group of the battery and/or from an average value of the voltage state of the respective terminal voltage of at least two groups of the battery is calculated. The voltage state of the terminal voltage of the at least one other group and/or the average value of the voltage state of the respective terminal voltage of at least two groups of the battery may in this case be from the same charging process and relaxation or from a previous charging process and a previous relaxation additionally under the same environmental condition in each case. The previous relaxation may in this case be before and/or after the previous charging process. In addition, provision may also be made for combinations of said embodiments of the method.

This results in the advantage that a state of health of the battery is able to be estimated reliably without interrupting a charging process on different charging devices under different environmental conditions. In particular, it is not necessary to interrupt the charging process for the estimation. An interruption of the charging process by the battery controller may irritate an external charging device, such that it assumes that the charging process has ended prematurely, and may therefore end the charging process prematurely. The method described above means that a charging process does not have to be interrupted since the proportion of defective battery cells is estimated for example at the start of the charging process, in particular during the first half of the charging process from the charging start time. This allows the estimation to be performed independently of the charging device.

Comparing the voltage state of the terminal voltage of the group during the charging process with the voltage state of the terminal voltage of the same group from a previous charging process under the same environmental condition or with the profile of the terminal voltage of another group of the battery during the current charging process furthermore results in the advantage that less memory is needed for reference data. Such reference data also have to be laboriously collected in a laboratory test and stored in the memory. In the method used above, only a limited number of temporal profiles from the previous charging process need to be stored in the memory together with the respective environmental condition. As soon as the environmental condition is the same environmental condition or at least an environmental condition similar within a tolerance interval, the voltage state is determined again by the battery controller in a current charging process and compared with the voltage state of the terminal voltage from the previous charging process. The comparison during the operation of the battery thus makes it possible to dispense with an extensive reference dataset. The limited number of temporal profiles may in this case comprise a number of charging processes such that a jumpy behaviour in the rate of change of the deviation is able to be detected, even if this occurs only after several charging cycles and only small rates of change, which do not suggest disconnectivity, occur in the first charging cycles.

Estimating the proportion of defective battery cells in one of the groups in the battery additionally results in the advantage that individual defective groups may be electrically isolated from the battery and a remaining part of the battery, comprising the other groups, may at least continue to be operated. In addition, a damaging effect of the defective battery cells on healthy battery cells, for example due to heat development and/or due to compensation currents between the battery cells and/or the groups of battery cells, may be reduced.

The voltage state of the terminal voltage of the group may be determined during the charging process, in particular during a discharging process, and/or the relaxation, on the one hand, and/or in each case before and/or after the charging process, in particular before and/or after the discharging process, and/or the relaxation, on the other hand. In other words, the determination of the terminal voltage may be determined during the charging process and additionally during the relaxation, that is to say before and/or after the charging process.

The charging process may be a recharging process or a discharging process. The recharging process may in this case be a preferred state for the method, since the motor vehicle is stationary during the recharging process and there are typically no voltage disturbances due to load from the drive or from regenerative braking. A deviation may accordingly be calculated more accurately.

In addition or as an alternative, the terminal voltage of the group may be determined after the charging process and a subsequent relaxation, on the one hand, or after the relaxation and a subsequent charging process, on the other hand. The voltage state of the terminal voltage may also be determined after the charging process when the battery has relaxed.

In addition or as an alternative, the voltage state may be determined during the charging process, in particular during a recharging and/or discharging process, and additionally before or after relaxation of the battery.

In addition or as an alternative, the terminal voltage of the group may be determined before and/or during and/or after relaxation.

In addition or as an alternative, the voltage state may be determined during a rest period of the battery that amounts at least partially to a time of the relaxation. This makes it possible to reduce a duration needed to determine the voltage state.

Determining the voltage state of the terminal voltage may comprise determining a voltage drop when the charging process ends and/or when the discharging process ends. In other words, a voltage drop may be compared, at the end of the charging process, in particular a charging and/or discharging process, with the voltage drop of the group from a previous charging process and/or with the voltage drop of the other group of the battery. The voltage state or in particular the voltage level is determined after the battery has relaxed and a deviation of the voltage state or in particular of the voltage level of the group under an environmental condition from the same group from a previous charging process under the same environmental condition and/or from another group of the battery is calculated. In particular, during the relaxation time, balancing of the battery may be suspended or paused until the deviation has been determined.

The proportion of defective battery cells in the group may be determined from the deviation, in particular from the deviation threshold value, by way of a decision function, for example a decision matrix. In other words, the decision function may map the deviation and/or the deviation threshold value onto a number of defective battery cells and/or a proportion of defective battery cells out of the total number of battery cells in the group. The decision function may be obtained for example from literature data and/or from test data. In particular, the decision function may be designed as a decision matrix, which assigns the deviation and/or the deviation threshold value to the proportion of defective battery cells. The decision matrix may for example be designed as a database. This results in the advantage that the proportion of defective battery cells is able to be estimated by way of a voltage measurement on the group.

If the deviation exceeds a deviation threshold value that varies with the environmental condition, the proportion of defective battery cells in the group, for example the proportion of battery cells electrically disconnected from the group, may be determined. In other words, the threshold may be a voltage threshold value and/or a resistance threshold value that varies with a difference between at least one parameter of the current charging process with the corresponding parameter of the previous charging process. If for example a temperature value of the environmental condition in the current charging process is twice as high as the temperature value of the environmental condition from the previous charging process, the deviation threshold value may likewise be twice as high as the deviation threshold value at which the temperature values of the environmental condition from the current and previous charging process are the same. This means that it is possible to use proportionality relationships between the terminal voltage and the respective environmental condition to reduce an amount of comparison data and thus a storage requirement.

If the proportion of defective battery cells exceeds a proportion threshold value, in particular if the deviation exceeds the deviation threshold value associated with the respective proportion of defective battery cells, the group may be electrically isolated from the battery by way of a switching arrangement and/or a charging current or a discharging current may be limited and/or a warning message may be output. In other words, if the number of defective battery cells exceeds a maximum permitted number of defective battery cells, which may be represented by the proportion threshold value, the group may be electrically isolated from the switching arrangement and thus from the battery. The deviation threshold value may be mapped onto the proportion threshold value by way of the decision function, in particular the decision matrix. If the deviation threshold value and/or the proportion threshold value are exceeded, the group may be electrically isolated. This results in the advantage that the battery still remains at least partially usable and any damaging effect of the defective battery cells in the group is limited. In the case of a limited discharging current, the motor vehicle may be operated in a restricted limp-home mode, that is to say emergency operation or emergency running mode, in order thus to be able to drive to a workshop. By way of example, in the limp-home mode, only those groups of the battery system whose proportion of defective battery cells falls below the proportion threshold value may be connected.

During the charging process, the voltage state of the terminal voltage and/or an electrical resistance of the same group and/or of the at least one other group under the environmental condition may be determined and stored in a memory together with the environmental condition. In other words, after the rest period has elapsed, a parameter of an environmental condition may be received and the voltage state of the terminal voltage may be stored in the memory together with the parameter. The parameter of the environmental condition may be for example a temperature and/or a state of charge of the battery during the rest period, and/or the rest period. The respective parameters may be determined by way of a sensor unit and received via a data connection, such as for example from the battery controller.

In addition or as an alternative, an internal electrical resistance of the group may be determined from a charging current or a discharging current and a terminal voltage of the group. Changing the internal electrical resistance likewise allows the battery controller to determine a proportion of defective battery cells in the group. For this purpose, the electrical resistance of the group may be determined in a current charging process, for example at the charging start time, and stored in the memory. For this purpose, the respective deviation threshold value may comprise a voltage threshold value and/or a resistance threshold value that may each be mapped onto the proportion threshold value by way of the decision function.

In particular, the deviation of the temporal profile and/or of the electrical resistance may be determined when the same environmental condition as or an environmental condition similar to in the previous charging process is determined during the charging process by way of a measurement of the respective parameters. The storage makes it possible to use the voltage state of the terminal voltage and/or the resistance in each case as a reference value for a subsequent charging process with the same environmental condition or at least an environmental condition similar within a tolerance range.

This results in the advantage that the proportion of defective battery cells is able to be better estimated by comparing the temporal profiles of the terminal voltage of the group and/or by comparing the internal resistance of the battery controller under different environmental conditions, on the one hand.

The voltage state of the terminal voltage and/or the electrical resistance of the same group under the environmental condition and/or of the at least one other group, optionally under the same environmental condition, may be determined during a start-up phase of the charging process, in particular at a start of the charging process. In other words, the electrical resistance may be determined at the start of the charging process. When the charging process is started with a charging current or discharging current, a voltage jump may occur, with the resistance being determined by way of the voltage jump at the start of the charging process. The voltage jump may in this case indicate a slope behaviour of the voltage and not a sudden difference between the rate of change of the deviation of the voltage state of the terminal voltage when the groups are disconnected. The voltage state of the terminal voltage may be determined during the start-up phase of the charging process, wherein the start-up phase of the charging process has a constant charging current or discharging current. In particular, a constant charging current limit may be set during the start-up phase to create a reproducible environmental condition, which charging current limit may for example be chosen to be so low that it is able to be achieved by different charging devices. In addition, it is possible to increase a sampling rate for determining the voltage state of the terminal voltage during the start-up phase, in particular during a constant current phase of the charging process.

At the charging start time, that is to say at the start of the charging process, the voltage state and/or the resistance of the group may be determined. For example, during a first half or a first quarter of the charging time from the charging start time, that is to say from the start of the charging process, the voltage state of the terminal voltage and/or the electrical resistance of the group may be determined. In particular, a deviation of the resistance may be determined from a difference in a voltage jump of the terminal voltage at the charging start time. This results in the advantage that an influence of the environmental condition on the charging behaviour may be reduced.

The voltage state of the terminal voltage and/or the electrical resistance may be determined under multiple environmental conditions and stored in the memory. The memory may for example be designed as a database in which the voltage state of the terminal voltage and/or the electrical resistance are stored in a manner categorized under the respective environmental condition.

This results in the advantage that the estimation of the defective battery cells is not distorted by the environmental conditions. In addition, owing to the storage under multiple environmental conditions, the estimation may be performed repeatedly for different environmental conditions. This also makes it possible to shorten an estimation interval.

A deviation of the electrical resistance from the electrical resistance of the same group from the previous charging process under the same environmental condition and/or from the electrical resistance of the at least one other group under the same environmental condition and/or from an average value of the electrical resistances of at least two groups of the battery may be calculated.

In other words, the deviation of the voltage state of the terminal voltage and/or the deviation of the resistance may be determined only when the current charging process meets the same environmental condition with regard to the parameters measured by the battery controller as the previous charging process. The environmental condition of the current charging process may additionally be the same environmental condition of the previous charging process when the respective parameter for determining the environmental condition is in a respective tolerance interval around the respective parameter value of the environmental condition of the previous charging process.

In particular, it is possible to use that stored voltage state of the terminal voltage and/or the electrical resistance whose previous charging process has the same environmental condition as the current charging process to calculate the deviation. This results in the advantage that the estimation may be performed by way of an additional parameter. Furthermore, this results in the advantage that an effect of the environmental condition on the estimation result may be reduced, since the determination of the resistance value fluctuates less with varying parameters of the environmental condition.

The environmental condition may comprise or be a charging current or a discharging current and/or a temperature and/or a state of charge of the battery and/or a rest period of the battery as parameter. The environmental condition may be a charging current interval or a discharging current interval and/or a temperature interval and/or a state of charge interval and/or a rest period interval. In other words, the environmental condition may use at least one parameter interval, which may be at least one tolerance interval from a charging current interval or discharging current interval and/or a temperature interval and/or a state of charge interval and/or a rest period interval around a respective reference parameter.

By way of example, the temperature interval may be ±5 kelvin around a reference temperature and/or the state of charge interval may be ±20% around a reference state of charge. As an alternative, a first state of charge interval may be in the range from 0 to 20%, a second may be from 20 to 40%, and a third may be from 60 to 80%. Likewise, by way of example, a first temperature interval may be in the range from 0° C. to 5° C., a second may be from 5° C. to 10° C., with the following temperature intervals being continued accordingly.

The rest period interval may for example amount to at least three quarters of a relaxation time, for example the entire relaxation time, up to a multiple of the relaxation time. The rest interval may be a time of inactivity of the battery, in particular at least partially a relaxation time of the battery. By way of example, the rest period may be between a rest period start and the charging start time. The rest period start may for example be determined by way of evaluating signals from a data bus system of a motor vehicle in relation to the speed of the motor vehicle and/or in relation to an operating state of a locking system and/or a heater (auxiliary heater or passenger compartment heater) of the motor vehicle and/or by way of measuring the presence of a charging current or discharging current, for example performed by a battery controller. Normally, the relaxation of the battery is determined by the battery current, which the battery controller of the battery is usually able to measure. If the battery current is zero or very small, the battery may start to relax. By way of example, the rest period may amount at least partially to the relaxation time. In particular, the rest period start may be determined as the time at which the speed of the motor vehicle is zero and at which a measured value of the charging current or discharging current is zero.

In addition or as an alternative, a signal may be received from the charging device that indicates that the motor vehicle is electrically connected to the charging device and the time of receipt of said signal may then be determined as the rest period start. If the motor vehicle is connected physically to the charging device, it is not able to drive and the drive therefore cannot draw power from the battery system. By way of example, the time at which a first signal is detected via a contact of a control pilot (CP) and/or a proximity pilot (PP), each of which indicates a connection to a charging plug of a charging device, may be determined as the rest period start. Charging may start after the rest period has elapsed. In addition, at least one switching element of a switching arrangement may be driven so as to electrically isolate the respective groups from a battery connection during the rest period, so that the respective group is able to relax when it is electrically isolated.

This results in the advantage that the dataset and thus a storage requirement may be reduced.

The environmental condition of the charging process may be the same environmental condition from the previous charging process when the respective parameter of the environmental condition has the same value as the respective parameter of the environmental condition from the previous charging process and/or when the respective parameter of the environmental condition is within a tolerance interval around a reference value of the respective parameter of the environmental condition from the previous charging process, wherein the reference value of the respective tolerance interval corresponds to the value of the respective parameter of the environmental condition from the previous charging process. In other words, the environmental condition of the current charging process and the environmental condition of the previous charging process may be the same environmental condition when the respective parameters from the current charging process and the previous charging process are within a tolerance interval around the respective parameter of the previous charging process. By way of example, the rest period before the current charging process may be in a tolerance interval around the rest period of the battery before the previous charging process reference value.

It is possible to use a parameter interval for the temperature and the state of charge and the rest period of the battery before the charging process, each of which determines a tolerance limit for the respective parameter. The voltage state of the terminal voltage and/or the resistance may be stored in the memory under the respective parameter of the environmental condition. This results in the advantage that the dataset and thus a storage requirement may be further reduced. It is furthermore possible to reduce an interval between the current and previous charging process in which the estimation of the defective proportion of the battery cells is performed.

The rest period may be determined from a time of inactivity of the battery and/or from a difference in a time between the rest period start and a charging start time t and/or after a relaxation time of the battery. The charging start time may be the time at which the charging current or discharging current is other than zero and/or exceeds a current threshold value. The rest period start may be the time at which the motor vehicle is connected to the charging device. In particular, for a charging target of the battery, for example a state of charge of 80 percent, a user may specify a charging target time at which the charging target should be achieved. Depending on the charging target and the charging target time and the charging current, the charging start time for the start of a charging process may be determined such that the charging target is able to be achieved at the charging target time. In addition, the rest period between the rest period start and the charging start time may in this case be determined such that the rest period amounts at least partially to the relaxation time of the battery, for example at least three quarters of the relaxation time.

In other words, the rest period may be a time of inactivity of the battery, in particular at least partially a relaxation time of the battery. The rest period may for this purpose be between a rest period start and the charging start time. The rest period start may be determined by way of evaluating signals from a data bus system of a motor vehicle in relation to the speed of the motor vehicle and/or in relation to an operating state of a locking system of the motor vehicle and/or by way of measuring a temporal profile of the charging current or discharging current. In particular, the rest period start may be determined as the time at which the speed of the motor vehicle is zero and at which the charging current or discharging current is zero. The voltage state of the terminal voltage may be determined when the rest period amounts at least partially to the relaxation time, such as for example at least three quarters of the relaxation time. The battery controller may determine the voltage state of the terminal voltage when the rest period amounts at least to the relaxation time.

In addition or as an alternative, a signal may be received from the charging device that the motor vehicle is electrically connected to the charging device and the time of receipt of said signal may be determined as the rest period start. The rest period start may thus begin when the motor vehicle is connected to the charging device. The rest period may therefore be the time between the rest period start and the charging start time. The charging start time may be calculated such that a charging target received by way of a user input is always achieved. The charging target may in this case be a reference state of charge of the battery after the charging process, for example a charging target time such as for example 6:00 a.m.

This results in the advantage that distortion of the estimation of the proportion of defective battery cells in the group due to hysteresis of the battery during charging and discharging is able to be avoided. In particular, the estimation method may be performed in a manner unnoticed by a user.

The above object is furthermore achieved by a battery controller, in particular a battery management system, having the features of claim 11.

The battery controller, in particular the battery management system, is configured to determine a proportion of defective battery cells in a group of battery cells connected electrically in parallel in a battery, wherein a processor unit is configured, by way of a measuring apparatus, to determine a voltage state of a terminal voltage of the group in relation to a charging process and/or in relation to a relaxation of the battery under an environmental condition and to calculate a deviation and additionally a rate of change of the deviation of the voltage state, determined by way of the measuring apparatus, of the terminal voltage from the voltage state, stored in a memory, of the terminal voltage of the same group from a previous charging process and/or a previous relaxation under the same environmental condition, on the one hand, and/or from the voltage state, stored in the memory, of the terminal voltage of at least one other group of the battery and/or from an average value of the voltage state of the respective terminal voltage of at least two groups of the battery, on the other hand, wherein the processor unit is configured to determine the proportion of defective battery cells in the group from the calculated deviation and additionally from the rate of change of the deviation.

The proportion of defective battery cells in the group may be determined by way of a comparison of the deviation with a stored deviation threshold value.

In other words, the battery controller may comprise a processing unit that is adapted such that it carries out the abovementioned method.

For this purpose, the battery controller may be configured to be connected to the measuring apparatus, in particular in order to measure the terminal voltage of the group, by way of a signal line. The battery controller may be designed to drive at least one switching element of a switching arrangement of the battery for opening and/or closure by way of the signal line. The switching elements in the switching arrangement allow a group whose proportion of defective battery cells exceeds a proportion threshold value to be electrically isolated from the battery and/or the other groups of the battery.

The battery controller may be configured to drive the switching element of the switching arrangement, when the deviation exceeds a deviation threshold value, such that the group is electrically isolated and/or a charging current is limited, for example by way of a precharging resistor, and/or a warning message is output. The warning message may for example comprise a request to a user to visit a workshop to replace the group of the battery system. For this purpose, the battery controller may be configured to output a signal for activating emergency operation of the battery in which the discharging current is limited. In addition, the battery controller may be configured to output the warning message as an indication to a workshop to replace the affected group. The proportion threshold value may for example be 50 percent. In other words, if for example the battery controller determines that half of the battery cells in the group are defective, the battery controller may electrically isolate the group by driving the respective switching elements and/or limit a charging current or a discharging current by way of a precharging resistor and/or output a warning message.

In addition, the battery controller may be designed to determine a rate of change of the deviation by way of a comparison of the calculated deviation in relation to a current charging process with the calculated deviation from at least one previous charging process, in particular in relation to a reference value from a previous charging process. By way of example, the battery controller may be designed to use the calculated deviation from the previous charging process in each case as a reference value for determining the rate of change. If for example the rate of change exceeds a threshold value in relation to the reference value, in particular if a jump in the rate of change is detected, the battery controller may be designed to determine that a swap from an old group to a new group has taken place. In this case, the battery controller may be designed to store the calculated deviation as a new reference value in a memory and additionally to output a signal not to disconnect the respective group if the rate of change exceeds said threshold value. If the rate of change falls below the threshold value, in particular no jump in the rate of change is detected, the battery controller may be designed to determine that the calculated deviation in relation to the charging process is caused by ageing of the battery cells in the group and/or by manufacturing tolerances.

For this purpose, the battery controller and in particular the battery management system may each be provided as an electronic control unit (ECU), which comprises at least one processor and/or at least one memory, the memory storing program instructions that cause the at least one processor to carry out said method. In other words, the battery controller and in particular the battery management system may each have a data processing device or at least one processor apparatus that is configured to perform the method described above. For this purpose, the processor apparatus may have at least one microprocessor and/or at least one microcontroller and/or at least one FPGA (field-programmable gate array) and/or at least one DSP (digital signal processor). Furthermore, the processor apparatus may have program code that is configured to perform the embodiment of said method when said program code is executed by the processor apparatus. The program code may be stored in a data memory or processor apparatus.

In addition or as an alternative, the battery controller and in particular the battery management system may be connected to the memory by way of a wired and/or a wireless data line in which the data in relation to the temporal profiles of the terminal voltage and/or the electrical resistance are stored. In addition, the deviation threshold value and/or the proportion threshold value may be stored in the memory or in another memory. The battery controller and in particular the battery management system may have the memory.

In addition, the battery controller may be designed to logarithmize the voltage state of the measured values in relation to the terminal voltage and/or the resistance by way of a filter element. This results in the advantage that the respective deviation may be calculated more efficiently by a processor apparatus, in particular a microcontroller.

The above object is furthermore achieved by a computer program having the features of Claim 12, which comprises instructions that, when the program is executed by the battery controller, in particular the battery management system, cause same to perform the method described above.

In other words, the computer program may preferably be implemented for an application for embedded systems. In addition, the computer program may be designed to be executed by way of a microcontroller, wherein the voltage state of the terminal voltage is logarithmized.

The invention additionally makes provision for a computer-readable storage medium having the features of claim 13, on which said computer program is stored.

In other words, the computer-readable storage medium may be a punch card, a (floppy disc) storage medium, a hard drive, a CD, a DVD, a USB (universal serial bus) storage device, a RAM (random access memory), a ROM (read-only memory) and/or an EPROM (erasable programmable read-only memory). Preferably, the computer-readable storage medium may be a RAM or a ROM, wherein a flash memory is in particular used. The computer-readable storage medium may also be a data communication network that enables downloading of a program code, such as for example the Internet, or other systems. The battery controller, in particular the battery management system, may in each case comprise the computer-readable storage medium.

The invention furthermore also makes provision for a battery having the features of claim 14, wherein the battery is designed in particular for a motor vehicle. The battery comprises said battery controller. The battery may be for example a lithium-ion battery. In addition, the battery may be designed as a distributed battery system.

The invention also makes provision for a motor vehicle having the features of claim 15, which comprises said battery and/or said battery controller.

The motor vehicle is designed for example as a motorized vehicle, in particular as a passenger car or truck, or as a passenger bus or motorcycle. The motor vehicle may be electrically driven (EV) or in particular a hybrid electric vehicle (HEV, PHEV).

The invention also comprises implementations that comprise a combination of the features of several of the described embodiments.

### BRIEF DESCRIPTION OF THE FIGURES

Preferred further embodiments of the invention will be explained in more detail through the following description of the figures, in which:

FIG. 1 shows a schematic illustration of a battery in a motor vehicle, which battery has at least one group of battery cells that each comprises a number of battery cells connected electrically in parallel;

FIG. 2 shows a schematic illustration of a discharging and charging process of a group of the battery in two different operating states at different times; and

FIG. 3 shows a schematic illustration of a method for ascertaining the proportion of defective battery cells in a group for a battery controller.

### DETAILED DESCRIPTION OF PREFERRED EXEMPLARY EMBODIMENTS

Preferred exemplary embodiments are described below with reference to the figures. In this case, identical, similar or functionally identical elements in the various figures are provided with identical reference signs, and a repeated description of these elements is in some cases dispensed with in order to avoid redundancies.

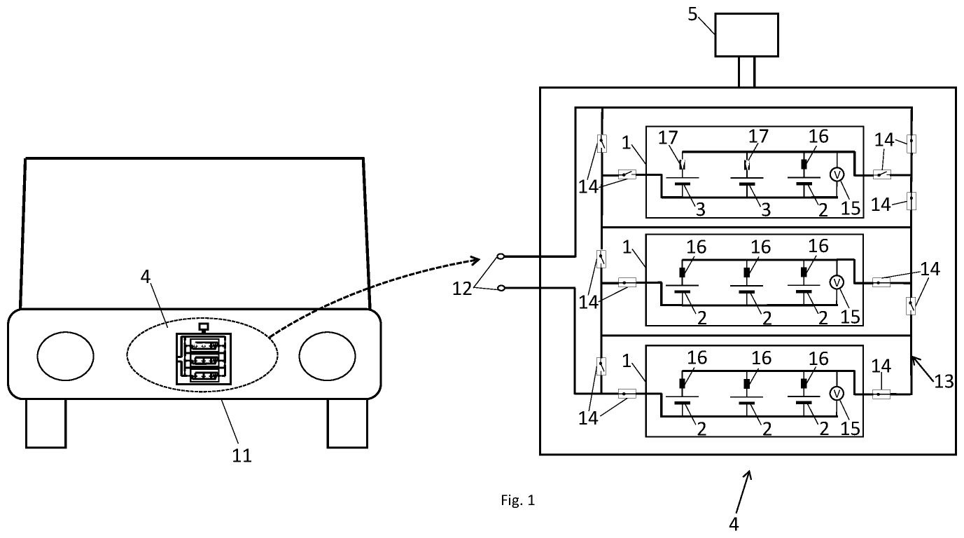

FIG. 1, on the left, schematically illustrates a motor vehicle 11 that comprises a battery 4. The battery 4 on the right in FIG. 1 has at least one group 1 that comprises a number of battery cells 2 and 3 connected electrically in parallel. The groups 1 are each connected electrically to one another in a series or in a parallel connection, in particular to the battery connection 12 via which a charging process and/or a discharging process of the battery 4 takes place, by way of the switching arrangement 13. A respective group 1 is able to be electrically isolated from the switching arrangement 13 and/or connected thereto by way of the switching elements 14 of the switching arrangement 13. In particular, the respective switching element 14 may for this purpose be driven by the battery controller 5 so as to open and/or close an electrical connection. For this purpose, the battery controller 5 may for example be designed as a battery management system.

The respective group 1 has a measuring apparatus 15 that is designed to measure a terminal voltage U of the respective group 1. Owing to the parallel connection of the battery cells 2 and 3 in the group 1, the battery cells 2 and 3 generally share the same voltage level. The battery controller 5 is designed to control a charging process, in particular a charging start time tₗ, a charging target Uₕ, and/or a charging time of the battery 4. The charging target Uₕ may in this case be a target state of charge of the battery 4, which may be specified by a user, such as for example a state of charge of 60, 70 or 80 percent, for which the group has a respective terminal voltage Uₕ.

The charging time may be a time forecast by the battery controller 5 that the battery 4 requires to reach the charging target Uₕ, with a charging current of the charging device being specified by a user. In particular, a user may specify a charging target time tₕ for the charging target Uₕ, at which target charging time the charging target Uₕ, is supposed to be achieved. Depending on the charging target Uₕ, and the charging target time tₕ and the charging current, the battery controller 5 may be designed to determine the charging start time tₗ for the start of a charging process such that the charging target Uₕ, is able to be achieved at the charging target time tₕ.

To determine a state of health of the battery 4, the battery controller 5 is additionally designed to receive measured data from the respective measuring apparatus 15 of a group 1 via a wired and/or wireless data connection and to store said measured data in a memory. In addition, the battery controller 5 is designed to determine a deviation of a current voltage state t₁, t₂ and t₃ of the measured value in relation to the terminal voltage U_{c} of the respective group 1 during a current charging process from the voltage state t₁, t₂ and t₃ of the measured value of the terminal voltage Uₚ of the same group 1 from a previous charging process under the same or a similar environmental condition.

In addition or as an alternative, the battery controller 5 may be designed to determine the deviation of the voltage state t₁, t₂ and t₃ of the measured value in relation to the terminal voltage U_{c} of the respective group 1 during the current charging process from the voltage state of the measured value of the terminal voltage Uₚ of another group 1, in particular a deviation of the current terminal voltage from a reference value. The reference value may for example be an average value of the temporal profiles of the t₁, t₂ and t₃ of the measured value in relation to the terminal voltage Uₚ of the other groups in the battery, in particular during the current charging process.

The state of health of the battery 4 may comprise a proportion of defective battery cells 17 out of the total number of battery cells 16 in the respective group 1. The respective group 1 may comprise healthy battery cells 2 and defective battery cells 3. Healthy battery cells 2 may age at different rates over time and/or due to environmental influences, such as for example manufacturing defects. As a result, healthy battery cells 2 may prematurely become defective battery cells 3 that have an increased internal electrical resistance R and a lower terminal voltage U than healthy battery cells 2 in the group 1. A defective battery cell 3 in the group 1 may lead to increased heat development during a charging and/or discharging process of the battery 4 and cause undesirable compensation currents. The defective battery cells 3 may therefore damage the healthy battery cells 2 in the battery 4.

In order to limit the damage to the healthy battery cells 2 caused by the defective battery cells 3, the respective battery cells 2 and 3 have a battery cell circuit breaker 16 and 17, wherein the healthy battery cells 2 have an electrically closed battery cell circuit breaker 16 and the defective battery cells 3 have an electrically open battery cell circuit breaker 17 for electrically isolating the defective battery cell 3 from the healthy battery cells 2 in the group 1. However, the battery cell circuit breakers 16 and 17 are often designed as an electrical fuse as a last resort to prevent damage, to which is activated when a threshold value, such as for example a temperature of the battery cells 2 and 3, is exceeded. For this reason, batteries 4 do not have a sensor arrangement so that opening or closure of the respective battery cell circuit breaker 16 and 17 is able to be read by the battery controller 5, and so the number of defective battery cells 3 is unknown to the battery controller 5. In addition, the boundary between a healthy battery cell 2 and a defective battery cell 3 may be blurred.

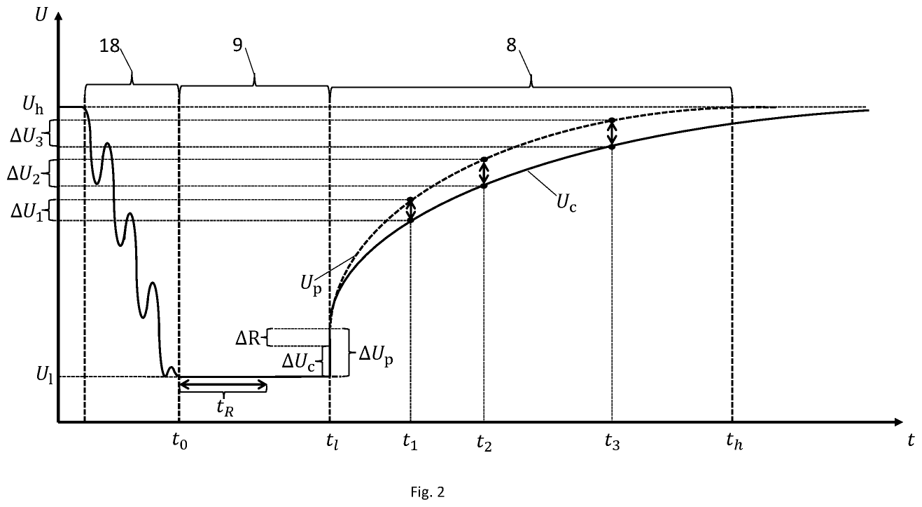

For the battery controller 5 to forecast the state of health of the battery 4, it is therefore advantageous for the battery controller 5 to estimate the proportion of defective battery cells 3, in particular the proportion of electrically isolated or defective battery cells 3, in the respective group based on a charging characteristic. The estimation of the proportion of defective battery cells 3 by way of the charging characteristic during a charging process is shown in FIG. 2.

FIG. 2 shows a schematic illustration of the voltage state t₁, t₂ and t₃ of the measured value in relation to the terminal voltage U_{c} of the group 1 during a discharging process 18, during the rest period 9 and during a charging process 8 of the battery 4. For comparison, FIG. 2 additionally shows the voltage state t₁, t₂ and t₃ of the measured value of an exemplary terminal voltage Uₚ of the same group 1 from a previous charging process 8 under the same environmental condition or a different group 1 from the same charging process 8 or from the previous charging process 8 under the same environmental condition.

The battery 4 initially has a state of charge at which the group has the terminal voltage Uₕ. The battery 4 in the motor vehicle 11 is then subsequently discharged. During the discharging process 18, the motor vehicle 4 requires electrical energy from the battery 4, which is delivered from the battery 4 to the motor vehicle 11 via the battery connection 12. During the discharging process 18, the terminal voltage U of the group 1 therefore drops. Brief fluctuations in a discharging rate may occur here, for example due to acceleration and/or recuperation of the motor vehicle 11.

When the battery 4 has been discharged sufficiently, the battery 4 has a second, low state of charge Uₗ at which the group 1 has the terminal voltage Uₗ. At the time of the rest period start t₀, the motor vehicle 11, for charging purposes, is connected to a charging device, such as for example a wallbox, in order to recharge the battery 4. The charging process 8 begins at the charging start time tₗ and ends when the charging target Uₕ, has been achieved at the terminal voltage Uₕ, at the charging target time tₕ.

After the rest period 9 has elapsed, the charging process 8 starts at the charging start time tₗ, to wherein the battery 4 is at least partially charged with a constant charging current via the battery connection 12 during the charging process 8. The rest period 9 may in this case amount at least partially to a relaxation time t_{R} of the battery 4, for example at least the relaxation time t_{R}. The battery controller 5 may for example determine the charging start time tₗ such that the charging target Uₕ, is achieved at the charging target time tₕ. In addition, the battery controller 5 may detect the rest period start t₀ when the motor vehicle 11 is connected to a charging device. By way of example, the charging process 8 may start when the relaxation time t_{R} has at least partially elapsed as rest period 9, such as for example three quarters of the relaxation time t_{R} of the battery 4 as a minimum condition.

The battery controller 5 is able here to measure the rise in the terminal voltage U_{c} of the group 1 during the charging process 8 by way of the measuring apparatus 15 at the times t₁, t₂ and t₃ and additionally to store the voltage state t₁, t₂ and t₃ of the measured values in a memory.

By way of example, the battery controller 5 is able to measure the terminal voltage U_{c} during the charging process 8 at regular time intervals by way of the measuring apparatus 15. In addition or as an alternative, the battery controller 5 may have a minimum number of measuring points during a start-up phase, in particular a constant current phase, of the charging process 8, at which the battery controller 5 performs a voltage measurement on the group 1 by way of the measuring apparatus 15. The battery controller 5 may in this case start to record the voltage state of the terminal voltage U_{c} as soon as the charging current from the charging start time tₗ remains constant in a first half of the charging time of the charging process 8.

The battery controller 5 determines the voltage state of the terminal voltage U_{c} under at least one environmental condition. The environmental condition may comprise a charging current or discharging current and/or a temperature and/or a state of charge Uₗ of the battery 4 and/or the rest period 9 of the battery 4 as parameter.

The battery controller 5 may use the parameters of the state of charge Uₗ and the temperature and the rest period of the battery 4 as the environmental condition under which the voltage state of the terminal voltage U_{c} is stored in the memory.

In addition or as an alternative, the battery controller 5 may use a parameter interval, in particular a charging current interval or discharging current interval and/or a temperature interval and/or a state of charge interval and/or a rest period interval, for the environmental condition. This makes it possible to reduce a dataset for storing the voltage state of the terminal voltage U_{c} under the environmental condition, and thus a storage requirement of the battery controller 5. The rest period interval may amount for example to at least three quarters of the relaxation time t_{R} up to a multiple of the relaxation time t_{R}. If a respective parameter, received by the battery controller 5, of the environmental condition from the current charging process 8 falls into the respective parameter interval of the environmental condition from the previous charging process 8, the battery controller 5 may determine that the same environmental condition is present.

A deviation ΔU₁, ΔU₂ and ΔU₃ of the voltage state t₁, t₂ and t₃ of the terminal voltage U_{c} of the group 1 during the charging process 8 from a voltage state t₁, t₂ and t₃ of the terminal voltage Uₚ of the same group 1 from a previous charging process 8 under the same environmental condition, for example under the same temperature interval and/or state of charge interval and/or the same rest period interval, is calculated by the battery controller 5.

For example, the battery controller may, at each sampling point of the measurement, form a difference between the terminal voltage U_{c} and the terminal voltage Uₚ and add up the absolute value of the respective differences. The deviation by way of the voltage state of the terminal voltage Uₚ is already stored in the memory for this purpose.

In addition or as an alternative, the battery controller 5 may calculate a deviation ΔU₁, ΔU₂ and ΔU₃ of the voltage state t₁, t₂ and t₃ of the terminal voltage U_{c} from a voltage state t₁, t₂ and t₃ of the terminal voltage Uₚ of another group 1 from the same charging process 8 or from a previous charging process 8 under the same environmental condition.

In addition or as an alternative, the battery controller 5 may determine an electrical resistance R₁ of the group during the charging process 8, for example at the charging start time tₗ, from the terminal voltage U_{c} the charging current. In addition, the battery controller 5 may calculate a deviation of the resistance R₁ from a resistance R₂ from the same group 1 from a previous charging process 8 and/or from the resistance R₂ from another group 1 from the same charging process 8 or from a previous charging process 8 under the same environmental condition. The resistance R₂ is stored for this purpose in the memory of the battery controller under the environmental condition. The battery controller 5 may determine the deviation of the resistance ΔR from a difference in the terminal voltage U_{c} and the terminal voltage Uₚ of the same group 1 from the current charging to process 8 and/or another, structurally identical group 1 from the current charging process 8 or a previous charging process 8 under the same environmental condition at the start of the charging process 8, for example at the charging start time tₗ. In particular, at the charging start time tₗ, the terminal voltages U_{c} and Uₚ may each increase abruptly, the battery controller 5 being able to determine the resistance change ΔR from the difference in the voltage jumps U_{c}−Uₚ.

If the deviation ΔU₁, ΔU₂ and ΔU₃ of the voltage state t₁, t₂ and t₃ of the terminal voltages U_{c} and Uₚ exceeds at least one voltage threshold and/or the deviation ΔR of the resistances R₁ and R₂ exceeds at least one resistance threshold value, in particular a voltage threshold value and/or resistance threshold value that varies in each case with the environmental condition, the battery controller 5 determines the proportion of defective battery cells 3 in the group 1, for example the proportion of battery cells 3 electrically isolated from the group 1.

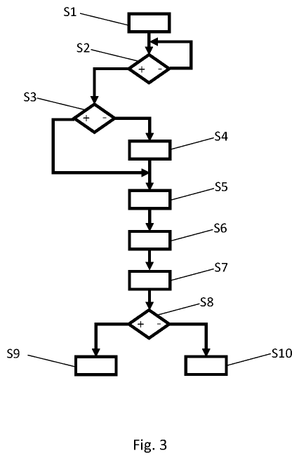

In particular, if the proportion of defective battery cells 3 in the group 1 exceeds a proportion threshold value, the battery control unit 5 may electrically isolate the group 1 from the other groups 1 of the battery 4 by way of the switching elements 14 of the switching arrangement 13. The effect of the defective battery cells 3 on the healthy battery cells 2 may thus be reduced. A method for the battery controller 5 is shown in FIG. 3.

FIG. 3 shows a schematic illustration of a method for ascertaining the proportion of defective battery cells in a group, for example for a battery controller 5. In a first step S1, it is determined that the battery 4 is in an inactive operating state. By way of example, a fluctuation in the terminal voltage U_{c} may be determined and, as long as a sum of the deviations of the fluctuation absolute values of the terminal voltage U_{c} exceeds an activity threshold value in a time interval, an active operating state of the battery 4 may be assumed. By way of example, during a relatively long journey with stops at fast-charging stations or through recuperation, the sum of the fluctuation absolute values may be above the activity threshold value, and so the method for determining the proportion of defective battery cells 3 does not start. If the sum of the fluctuation absolute values of the terminal voltage U_{c} falls below the activity threshold in the time interval, the rest period start t₀ may be determined.

In particular, the rest period start t₀ may be determined when a signal is received that the speed of the motor vehicle 11 is zero and a locking system of the motor vehicle 11 is locked. In addition or as an alternative, a charging current, flowing from the charging device to the motor vehicle, may be measured by way of the measuring apparatus 15 and the time at which the measurement of the charging current is other than zero may be determined as rest period start t₀. The measuring apparatus 15 may for this purpose also be designed for a current measurement. In addition, the respective groups may be electrically isolated from the battery connection 12 over the duration of the rest period 9 by way of the switching elements 14 of the switching arrangement 13.

In a second step S2, it is determined whether a charging process 8 should be performed. By way of example, it may be determined that a charging process 8 is present as soon as a charging current, flowing to the battery 4 via the battery connection 12, is measured by way of the measuring apparatus 15. In addition or as an alternative, it is possible to receive a user input that a charging process 8 has been started. As long as no charging process is determined, step S2 may be repeated. The respective group 1 of the battery 4 may be electrically connected to the battery connection 12, by way of the switching elements 14 of the switching arrangement 13, when a user input that a charging process 8 should be performed has been received.

In a third step S3, it is established whether the battery 4 had a sufficient rest period before the charging start, in particular before the charging start time tₗ. During the rest period 9, the respective groups 1 of the battery 4 may additionally be electrically isolated from the battery connection 12 by way of the switching elements 14 of the switching arrangement 13, such that the groups rest during the rest period 9. By way of example, the rest period start t_{R} may be determined by way of evaluating the signals in relation to the speed of the motor vehicle 11 and/or a locking system of the motor vehicle 11 and/or by way of measuring a temporal profile of the charging current.

In particular, the rest period start t_{R} may be determined as the time at which the speed of the motor vehicle 11 is zero and at which a measured value of the charging current or discharging current is equal to 0 A. In addition or as an alternative, a signal may be received from the charging device that the motor vehicle 11 is electrically connected to the charging device and the time of receipt of said signal may be determined as the rest period start t_{R}.

The rest period 9 may amount at least partially to a relaxation time t_{R} of the battery 4. The rest period 9 may be at least the relaxation time t_{R} of the battery 4. If a charging target Uₕ and/or a charging target time tₕ are/is received by way of a user input, the charging start time tₗ may be determined by way of a forecast such that the battery 4 rests over the rest period 9 from the rest period start t_{R} and the charging target Uₕ is achieved at the charging target time tₕ. For this purpose, the expected charging duration may be forecast for example by way of determining the charging current, in particular a charging current reference value, of the charging device and the charging target Uₕ.

In a fourth step S4, the charging process 8 is started. A constant charging current may be set in this case. In particular, the charging current may be set to a charging current reference value to which the battery 4 is charged.

While a constant charging current is measured by way of the measuring apparatus 15 during the charging process, for example at least in a first half of the charging time from the charging start time tₗ, the terminal voltage U_{c} of the respective group 1 of the battery 4 may be measured at different times t₁, t₂ and t₃ in particular periodically.

By way of example, during the start-up phase of the charging process, in particular during the constant current phase, the voltage state t₁, t₂ and t₃ of the terminal voltage U_{c} may be determined under at least one environmental condition. The environmental condition may comprise a charging current or discharging current and/or a temperature and/or a state of charge Uₗ of the battery 4 and/or the rest period 9 of the battery 4 as parameter. By way of example, to determine the environmental condition for the current charging process 8, a temperature value from a temperature sensor of the motor vehicle 11 and/or the battery 4 may be received.

In addition or as an alternative, in the fourth step S4, an electrical resistance R₁ of the group 1 or of another group 1 of the battery 4 may be determined during the charging process 8, for example at the charging start time tₗ.

In a fifth step S5, the measured data in relation to the terminal voltage U_{c} of the group 1 and additionally of at least one other group 1 from the charging process 8 are stored in a memory, in particular in a memory of the battery controller 5. The measured values are stored in the memory as a voltage state of the terminal voltage U_{c}.

In addition or as an alternative, in the fifth step S5, a value of the electrical resistance R₁ of the group 1 and/or of another group 1 of the battery 4 may be stored in the memory. The voltage state t₁, t₂ and t₃ of the terminal voltage U_{c} are stored in the memory together with the environmental condition.

In addition or as an alternative, the environmental condition comprises a parameter interval, in particular a charging current interval or discharging current interval and/or a temperature interval and/or a state of charge interval and/or a rest period interval. By way of example, the temperature interval may be ±5 kelvin and/or the state of charge interval may be ±20%. If for example the respective parameter of the environmental condition, during the current charging process 8, is in the respective parameter interval of the environmental condition from the previous charging process 8, the voltage state t₁, t₂ and t₃ of the terminal voltage U_{c} may be associated with the environmental condition of the voltage state t₁, t₂ and t₃ of the terminal voltage Uₚ from the previous charging process 8, and in particular stored in the memory in a manner categorized together with the environmental condition. If for example the battery 4, at a temperature of 5° C., has a state of charge of 30% during the rest period comprising the relaxation time t_{R}, the voltage state of the terminal voltage U_{c} during the charging process 8 may be stored in the memory in a manner categorized under the second temperature interval and/or the first state of charge interval and/or the relaxation time t_{R} as environmental condition.

In a sixth step S6, the voltage state of the terminal voltage U_{c} from the charging process 8 is compared with the voltage state of the terminal voltage Uₚ of the same group 1 from the previous charging process 8 under the same environmental condition and/or with the voltage state of the terminal voltage Uₚ of another group 1 from the same or the previous charging process 8 under the same environmental condition.

In addition or as an alternative, in the sixth step S6, the value of the electrical resistance R₁ may be compared with the value of the resistance R₂ of the same group 1 from the previous charging process 8 and/or with the value of the resistance R₂ of the other group 1 of the battery 4 from the same or the previous charging process 8 under the same environmental condition.

In a seventh step S7, a deviation ΔU₁, ΔU₂ and ΔU₃ of the voltage state t₁, t₂ and t₃ of the terminal voltage U_{c} from the voltage state t₁, t₂ and t₃ of the terminal voltage Uₚ is calculated and in addition the deviation ΔU₁, ΔU₂ and ΔU₃ is stored in the memory. In addition or as an alternative, a deviation ΔR of the resistance R₁ from the resistance R₂ is calculated for example at the charging start time tₗ and additionally ΔR stored in the memory.

In an eighth step S8, the deviation ΔU₁, ΔU₂ and ΔU₃ of the voltage state t₁, t₂ and t₃ of the terminal voltage U and/or the deviation ΔR of the resistance R from at least one respective deviation threshold value, in particular at least one voltage threshold value and/or at least one resistance threshold value, is used to determine the proportion of defective battery cells in the group 1 by way of the decision function, in particular by way of the decision matrix.

If the proportion of defective battery cells does not exceed the proportion threshold value, in a ninth step S9, the respective switching elements 14 of the switching arrangement 13 are driven such that the group 1 remains electrically connected to the other groups 1 of the battery 4 and the charging process 8 is able to be continued with the group 1.

If the proportion of defective battery cells exceeds the proportion threshold value, in a tenth step S10, the group 1 is electrically isolated from the other groups 1 of the battery 4 by way of at least one switching element 14 of the switching arrangement 13 and/or a charging current or discharging current is limited and/or a warning message is output.

Where applicable, all individual features set forth in the exemplary embodiments may be combined with one another and/or exchanged without departing from the scope of the invention.

### LIST OF REFERENCE SIGNS

1 Group
2 Battery cell
3 Defective battery cell
4 Battery
5 Battery controller
t₁, t₂, t₃ Voltage state
U, U₁, U₂ Terminal voltage
8 Charging process
9 Rest period
R₁, R₂ Electrical resistance
11 Motor vehicle
12 Battery connection
13 Switching arrangement
14 Switching element
15 Measuring apparatus
16 Battery cell circuit breaker (closed)
17 Battery cell circuit breaker (open)
18 Discharging process
Uₕ Charging target
Uₗ State of charge
t_{R} Relaxation time
tₗ Charging start time
tₕ Charging target time
t₀ Rest period start
S1 Step 1
S2 Step 2
S3 Step 3
S4 Step 4
S5 Step 5
S6 Step 6
S7 Step 7
S8 Step 8
S9 Step 9
S10 Step 10
S11 Step 11

1: A method for determining a proportion of defective battery cells in a group of battery cells connected electrically in parallel in a battery, wherein a voltage state of a terminal voltage of the group is determined in relation to at least one of: a charging process and a relaxation of the battery under an environmental condition and a deviation and additionally a rate of change of the deviation of the determined voltage state of the terminal voltage from the voltage state of the terminal voltage of a same group from at least one of: a previous charging process and a previous relaxation under a same environmental condition is calculated, wherein the proportion of defective battery cells in the group is determined from the calculated deviation and additionally from the rate of change of the deviation.

2: A method for determining a proportion of defective battery cells in a group of battery cells connected electrically in parallel in a battery, wherein a voltage state of a terminal voltage of the group is determined in relation to at least one of: a charging process and a relaxation of the battery under an environmental condition and a deviation and additionally a rate of change of the deviation of the determined voltage state of the terminal voltage from at least one of: a voltage state of the terminal voltage of at least one other group (1) of the battery (4) and an average value of the voltage state of the respective terminal voltage of at least two groups of the battery is calculated, wherein the proportion of defective battery cells in the group is determined from the calculated deviation and additionally from the rate of change of the deviation.

3: The method according to claim 1, wherein
the voltage state of the terminal voltage of the group is determined during at least one of: the charging process, the relaxation, in each case before the charging process, and in each case after the charging process.

4: The method according to claim 3, wherein determining the voltage state of the terminal voltage comprises determining a voltage drop when at least one of: the charging process ends and the discharging process ends.

5: The method according to claim 4, wherein the proportion of defective battery cells in the group is at least one of: determined from the calculated deviation by way of a decision function and determined by way of a comparison of the calculated deviation with a stored deviation threshold value.

6: The method according to claim 5, wherein if the deviation exceeds a deviation threshold value dependent on the environmental condition, the proportion of defective battery cells in the group is determined.

7: The method according to claim 6, wherein if the proportion of defective battery cells exceeds a proportion threshold value, at least one of: the group is electrically isolated from the battery by way of a switching arrangement, a charging current is limited, a discharging current is limited, and a warning message is output.

8: The method according to claim 7, wherein, during the charging process, the voltage state of the terminal voltage of at least one of: the same group and of the at least one other group under the environmental condition is determined and the determined voltage state of the terminal voltage is stored in a memory together with the environmental condition.

9: The method according to claim 8, wherein the voltage state of the terminal voltage of at least one of: the same group and the at least one other group under the environmental condition is determined during a start-up phase of the charging process.

10: The method according to claim 9, wherein the environmental condition comprises at least one of: a charging current, a discharging current, a temperature, a state of charge of the battery, and a rest period of the battery.

11: A battery controller configured to determine a proportion of defective battery cells in a group of battery cells connected electrically in parallel in a battery, wherein a processor unit is configured, by way of a measuring apparatus, to determine a voltage state of a terminal voltage of the group in relation to at least one of: a charging process and a relaxation of the battery under an environmental condition and to calculate a deviation and additionally a rate of change of the deviation of the voltage state, determined by way of the measuring apparatus, of the terminal voltage from a voltage state, stored in a memory, of the terminal voltage of a same group from at least one of: a previous charging process, a previous relaxation under a same environmental condition, and a voltage state, stored in a memory, of at least one of: the terminal voltage of at least one other group of the battery and an average value of the voltage state of the respective terminal voltage of at least two groups of the battery, wherein the processor unit is configured to determine a proportion of defective battery cells in the group from the measured deviation and additionally from the rate of change of the deviation.

12: A computer program comprising instructions that are configured to be executed by a battery controller configured to determine a proportion of defective battery cells in a group of battery cells connected electrically in parallel in a battery, wherein a processor unit is configured, by way of a measuring apparatus, to determine a voltage state of a terminal voltage of the group in relation to at least one of: a charging process and a relaxation of the battery under an environmental condition and to calculate a deviation and additionally a rate of change of the deviation of the voltage state, determined by way of the measuring apparatus, of the terminal voltage from a voltage state, stored in a memory, of the terminal voltage of a same group from at least one of: a previous charging process, a previous relaxation under a same environmental condition, and a voltage state, stored in a memory, of at least one of: the terminal voltage of at least one other group of the battery and an average value of the voltage state of the respective terminal voltage of at least two groups of the battery, wherein the processor unit is configured to determine a proportion of defective battery cells in the group from the measured deviation and additionally from the rate of change of the deviation

13: A computer-readable storage medium on which a computer program is stored comprising steps for a battery controller configured to determine a proportion of defective battery cells in a group of battery cells connected electrically in parallel in a battery, wherein a processor unit is configured, by way of a measuring apparatus, to determine a voltage state of a terminal voltage of the group in relation to at least one of: a charging process and a relaxation of the battery under an environmental condition and to calculate a deviation and additionally a rate of change of the deviation of the voltage state, determined by way of the measuring apparatus, of the terminal voltage from a voltage state, stored in a memory, of the terminal voltage of a same group from at least one of: a previous charging process, a previous relaxation under a same environmental condition, and a voltage state, stored in a memory, of at least one of: the terminal voltage of at least one other group of the battery and an average value of the voltage state of the respective terminal voltage of at least two groups of the battery, wherein the processor unit is configured to determine a proportion of defective battery cells in the group from the measured deviation and additionally from the rate of change of the deviation.

14: A battery for a motor vehicle, comprising a battery controller configured to determine a proportion of defective battery cells in a group of battery cells connected electrically in parallel in a battery, wherein a processor unit is configured, by way of a measuring apparatus, to determine a voltage state of a terminal voltage of the group in relation to at least one of: a charging process and a relaxation of the battery under an environmental condition and to calculate a deviation and additionally a rate of change of the deviation of the voltage state, determined by way of the measuring apparatus, of the terminal voltage from a voltage state, stored in a memory, of the terminal voltage of a same group from at least one of: a previous charging process, a previous relaxation under a same environmental condition, and a voltage state, stored in a memory, of at least one of: the terminal voltage of at least one other group of the battery and an average value of the voltage state of the respective terminal voltage of at least two groups of the battery, wherein the processor unit is configured to determine a proportion of defective battery cells in the group from the measured deviation and additionally from the rate of change of the deviation.

15: A Motor vehicle comprising at least one of: a battery for a motor vehicle and a the battery controller configured to determine a proportion of defective battery cells in a group of battery cells connected electrically in parallel in a battery, wherein a processor unit is configured, by way of a measuring apparatus, to determine a voltage state of a terminal voltage of the group in relation to at least one of: a charging process and a relaxation of the battery under an environmental condition and to calculate a deviation and additionally a rate of change of the deviation of the voltage state, determined by way of the measuring apparatus, of the terminal voltage from a voltage state, stored in a memory, of the terminal voltage of a same group from at least one of: a previous charging process, a previous relaxation under a same environmental condition, and a voltage state, stored in a memory, of at least one of: the terminal voltage of at least one other group of the battery and an average value of the voltage state of the respective terminal voltage of at least two groups of the battery, wherein the processor unit is configured to determine a proportion of defective battery cells in the group from the measured deviation and additionally from the rate of change of the deviation.

16: The method according to claim 1, wherein the charging process is a recharging process.

17: The method according to claim 2, wherein the charging process is a recharging process.

18: The method according to claim 5 wherein the decision function is a decision matrix.

19: The method according to claim 6, wherein the proportion of defective battery cells in the group comprises the proportion of battery cells electrically disconnected from the group.

20: The method according to claim 9, wherein the environmental condition is determined at a start of the charging process.
